(19) United States
(12) Patent Application Publication
(10) Pub. No.: US 2003/0008453 A1
(43) Pub. Date: Jan. 9, 2003

(54) Semiconductor device having a contact window and fabrication method thereof

(75) Inventors: Hyuck-Jin Kang, Seoul (KR); Tai-Heui Cho, Suwon-city (KR)

Correspondence Address: MARGER JOHNSON & McCOLLOM, P.C., 1030 S.W. Morrison Street, Portland, OR, 97205, US

(73) Assignee: Samsung Electronics Co., Ltd., Suwon-city (KR)

(21) Appl. No.: 10/115,363

(22) Filed: Apr. 1, 2002

(30) Foreign Application Priority Data
Jul. 4, 2001 (KR) 2001-39762
Jul. 4, 2001 (KR) 01-09762

(51) Int. Cl. H01L 21/8242; H01L 21/3205; H01L 21/4763; H01L 21/336

(52) U.S. Cl. 438/239; 438/586

(57) ABSTRACT

A semiconductor memory device and a fabrication method thereof are provided. A plurality of gate electrode patterns is formed on a semiconductor substrate having isolation regions. Spacers are formed on sidewalls of the gate electrode patterns. A disposable pattern is formed on contact window area. An intermediate insulating pattern is formed except on the contact window area. The disposable pattern is removed to define a contact window. A contact node pattern is formed in the contact window.

This application relies for priority upon Korean Patent Application No. 2001-39762, filed on Jul. 4, 2001, the contents of which are herein incorporated by reference in their entirety.

### FIELD OF THE INVENTION

The present invention relates to semiconductor devices having a contact window and fabrication methods thereof and, more particularly, to DRAM (Dynamic Random Access Memory) devices and fabrication method thereof.

### BACKGROUND OF THE INVENTION

In the continuing trend to higher memory capacity, various technologies have been proposed to increase the packing density of DRAM devices. As one of these technologies, a SAC (Self-Aligned Contact) technology has been widely used to make a contact window between conductive patterns, wherein the space between the conductive patterns is significantly reduced.

The conventional SAC technology for forming a self-aligned contact window will be described below with reference to the accompanying drawings of FIGS. 1 through 3. The drawings are sectional views showing the sequential process steps of the SAC technology in manufacturing of a DRAM device.

Referring to FIG. 1, an isolation region 12 is formed on a semiconductor substrate 10 to define an active region 13 of the substrate 10. On the resultant structure, a gate dielectric layer 14, a polysilicon layer 16, a tungsten silicide layer 18 and a silicon nitride mask layer 20 are stacked sequentially. The stacked layers are patterned into a plurality of gate electrode patterns 70 by a photolithography process. Each of the gate electrode patterns 70 is separated from the others by a selected distance. A silicon nitride spacer layer is formed on the substrate 10 and the gate electrode patterns 70. The spacer layer is etched back to form spacers 22 on the sidewalls of the gate electrode patterns 70.

Referring to FIG. 2, an intermediate insulating layer is formed on the gate electrode patterns 70 and fills the space therebetween. Subsequently, a CMP (Chemical Mechanical Polishing) process is performed to remove an upper portion of the intermediate insulating layer and to expose the top surface of the gate electrode patterns 70. As a result, intermediate insulating patterns 24 are formed. On the resultant structure, photoresist patterns 26 are formed to define contact window areas and to expose a selected portion of the intermediate insulating patterns 24.

Referring to FIG. 3, the selected portion of the intermediate insulating patterns 24 are removed by a plasma dry etching process using the photoresist patterns 26 as etching masks. As a result, a portion of the spacers 22 and a portion of the substrate 10 are exposed and the exposed portion of the spacers 22 and the remaining portion of the intermediate insulating patterns 24 define self-aligned contact windows. The silicon nitride spacers 22 have a low etch rate during the plasma etching process

After removing the photoresist pattern 26, a polysilicon layer is formed on the remaining portion of the intermediate insulating patterns 24 and in the contact windows. The CMP process is performed again to remove an upper portion of the polysilicon layer to expose the top surface of the gate electrode patterns 70. As a result, the polysilicon layer is patterned into contact node patterns 28 in the contact windows to complete the SAC technology. Each of the contact node patterns 28 is separated from the others.

After the formation of the contact node patterns 28, though not shown, either a bit line or a storage capacitor is electrically connected to the each of the contact node patterns 28. In case of COB (Capacitor-Over-Bitline) cell structures, the bit line is formed first. And then, the storage capacitor is formed over the bit line. The bit line is electrically connected to a portion of the contact node patterns 28 through a DC (Direct Contact) window, and the storage capacitor is electrically connected to the other portion of the contact node patterns 28 through a BC (Buried Contact) windows. During the formation processes of the DC and BC windows, the SAC technology can be used again in similar ways.

The SAC technology has been a very useful technology to make a contact window between gate electrode patterns 70, while the space between the gate electrode patterns 70 is significantly reduced. This is because it is possible to reduce the diameter of the contact window to be less than the minimum photolithographic feature size by using the SAC technology.

However, the SAC technology has several problems as follows. Generally, the plasma dry etching process is performed excessively to perfectly remove the selected portion of the intermediate insulating patterns 24 and to perfectly expose the portion of the substrate 10. Therefore, the plasma etching process may induce surface damage on the substrate 10. The damage may be so serious as to increase contact resistance or to increase trap charge density. The increased trap charge density may have an unfavorable effect on threshold voltage characteristic and refresh characteristic.

Meanwhile, use of the silicon nitride spacers 22 may induce a tensile stress at the boundary between the silicon nitride spacers 22 and the substrate 10 so as to induce a GIDL (Gate Induced Drain Leakage) problem. The silicon nitride spacers 22 may also induce unfavorable parasitic capacitance between the contact node patterns 28 and the gate electrode patterns 70. This is because the spacers 22 are made of silicon nitride having a high dielectric constant. Moreover, the parasitic capacitance can be increased due to the excessive plasma dry etching. That is to say, the dry etching process may remove a portion of the spacers 22 and reduce a distance between the contact node patterns 28 and the gate electrode patterns 70. The reduced distance increases the parasitic capacitance.

### SUMMARY OF THE INVENTION

It is an object of the present invention to provide a method for forming a semiconductor memory device, while there is no substantial damage on the substrate during a contact window is formed so as to improve threshold voltage characteristic and refresh characteristic comparing the SAC technology.

It is another object of the present invention to provide a method for forming a semiconductor memory device having a contact window, which substantially suppresses the GIDL problem.

It is another object of the present invention to provide a method for forming a semiconductor memory device having a contact window, which reduces unfavorably high parasitic capacitance between the contact node patterns and the gate electrode patterns.

According to one aspect of the present invention, a method of fabricating a semiconductor device is provided. The method comprises forming a plurality of conductive patterns on a substrate. The conductive patterns are preferably gate electrode patterns of transistors. A plurality of spacers is formed on sidewalls of the conductive patterns. The spacers are formed of silicon oxide. A disposable pattern is formed on a first portion of the spacers and on a first portion of the substrate. The disposable pattern exposes a second portion of the spacers and a second portion of the substrate. The disposable pattern is formed of a photoresist layer, and the top surface of the disposable pattern is higher than the top surface of the plurality of the conductive patterns. An intermediate insulating pattern is formed on the exposed second portion of the spacers and on the exposed second portion of the substrate. The process of forming the intermediate insulating pattern preferably comprises forming an intermediate insulating layer at a temperature under a meting point of the disposable pattern, and removing a portion of the intermediate insulating layer to expose the top surface of the disposable pattern. The intermediate insulating layer covers the disposable pattern. The intermediate insulating layer may be subjected to a soft bake process. The intermediate insulating layer is formed of a material selected from the group consisting a spin-on glass and an oligomer polysilazane. Subsequently, the disposable pattern is removed to expose the first portion of the spacers and the first portion of the substrate. The intermediate insulating pattern defines a contact window. The contact window may expose further a portion of the insulating masks. The intermediate insulating pattern has a significantly low etch rate against a process condition for the removal of the disposable pattern. The intermediate insulating pattern may be subjected to a hard bake process after the removal of the disposable pattern. A contact layer is formed in the contact window and on the intermediate insulating pattern. The contact layer is electrically contacted to the substrate. A portion of the contact layer and a portion of the intermediate insulating pattern are preferably removed to expose the top surface of the conductive pattern to leave a contact node pattern in the contact window.

According to another aspect of the present invention, a method of fabricating a semiconductor device is provided. A substrate comprises a lower insulating layer and a lower conductive pattern. The lower conductive pattern is preferably a portion of an active region or a lower contact node pattern. The lower contact node pattern which is formed between gate electrode patterns of transistors. A plurality of conductive patterns is formed on the substrate. A plurality of spacers is formed on sidewalls of the conductive patterns. A disposable pattern is formed on a first portion of the spacers and on a first portion of the substrate. The disposable pattern exposes a second portion of the spacers and a second portion of the substrate. An intermediate insulating pattern is formed on the exposed second portion of the spacers and on the exposed second portion of the substrate. Subsequently, the disposable pattern is removed to expose the first portion of the spacers and the first portion of the substrate. The intermediate insulating pattern defines a contact window, which exposes a portion of the lower conductive pattern. A contact layer is formed in the contact window and on the intermediate insulating pattern. The contact layer is electrically contacted to the substrate. The contact layer may be electrically connected to either a storage electrode or a bit line electrode of a dynamic random access memory cell.

### BRIEF DESCRIPTION OF THE DRAWINGS

Other features of the present invention will be more readily understood from the following detail description of specific embodiment thereof when read in conjunction with the accompanying drawings, in which:

FIGS. 1 through 3 are cross-sectional views illustrating the sequential process steps of the conventional method for forming a self-aligned contact window in manufacturing of a DRAM device.

FIGS. 4 through 13 are cross-sectional views illustrating the sequential process steps for forming a contact window according to the present invention; and

FIG. 14 is plan view illustrating a photoresist pattern in connection with FIG. 6, a DC window in connection with FIG. 12, and a BC window in connection with FIG. 13 according to the present invention.

FIG. 15 is plan view illustrating an elliptical active region in a cell array area according to the present invention.

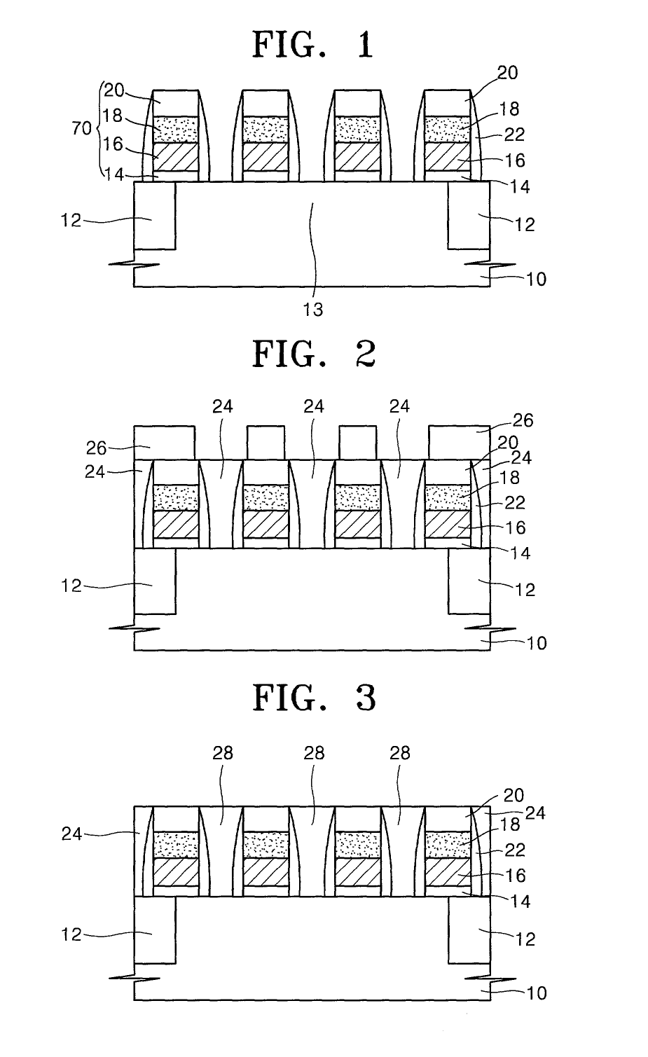

### DESCRIPTION OF THE PREFERRED EMBODIMENT

Preferred embodiments of the present invention will be described hereinafter with reference to the accompanying drawings, even though the scope of the present invention is not limited to the embodiments. In drawings, the thickness of layer or region is exaggerated for clarity. Also, when it is written that a layer is formed “on” another layer or a substrate, other layers may intervene therebetween.

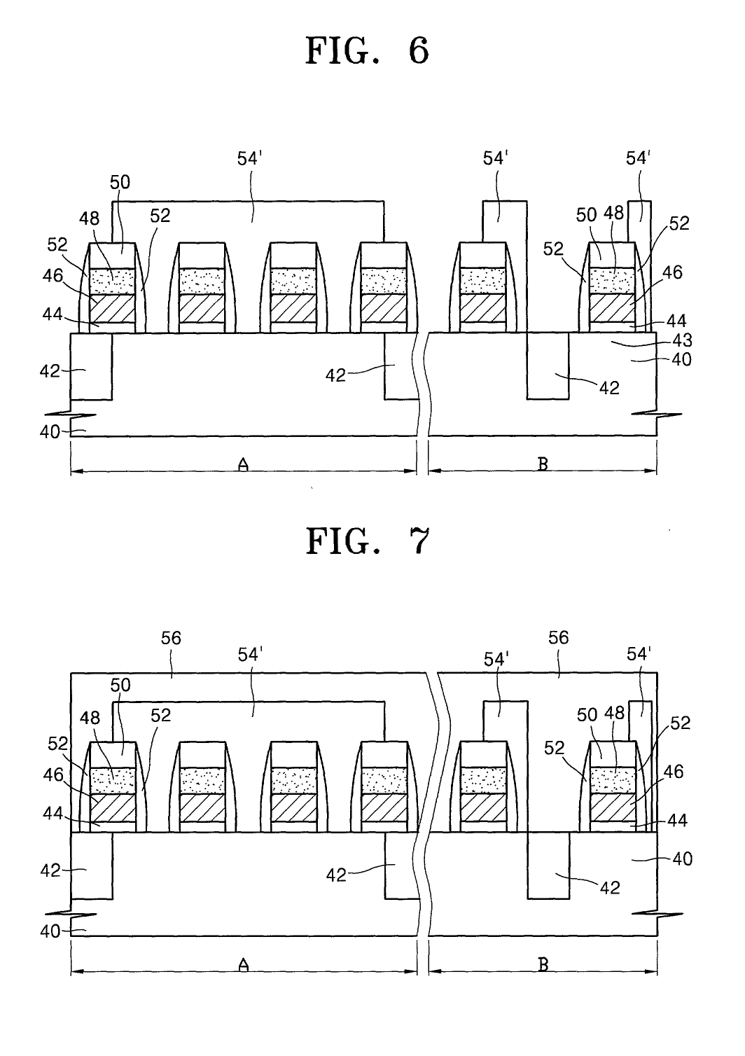

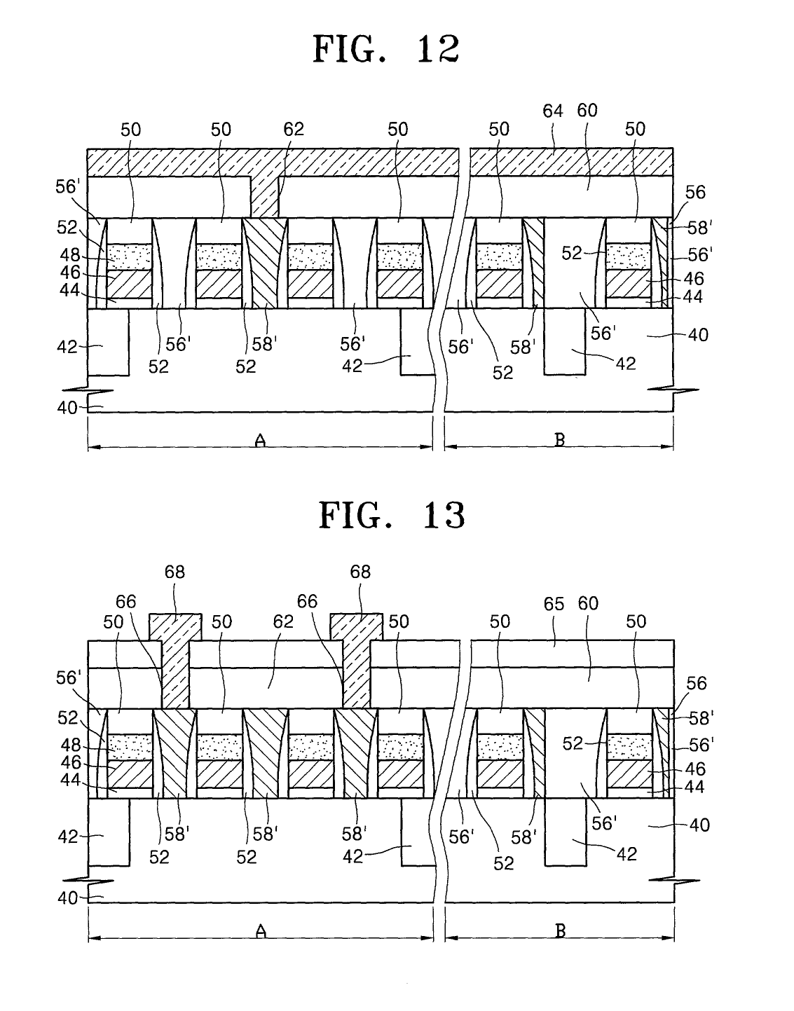

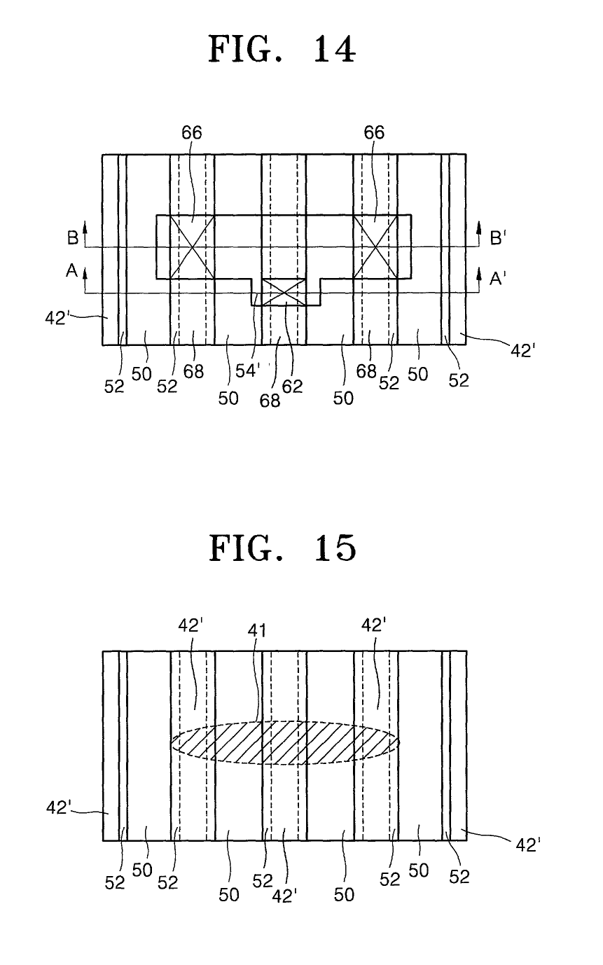

FIGS. 4 through 13 are cross-sectional views illustrating the process steps for forming a contact window according to the present invention. In the drawings, the reference symbols “A” and “B” indicate a cell array area and a core/peripheral area, respectively. FIG. 14 is plan view illustrating a photoresist pattern at the cell array area in connection with FIG. 6, a DC window in connection with FIG. 12, and a BC window in connection with FIG. 13. FIGS. 6 and 13 are cross-sectional views which are taken along a line B-B′ of FIG. 14, and FIG. 12 is cross-sectional view which is taken along a line A-A′ of FIG. 14.

Referring to FIG. 4, isolation regions 42 are formed on a semiconductor substrate 40 either by a LOCOS (Localized Oxidation of Silicon) method or by a STI (Shallow Trench Isolation) method. The isolation regions 42 define active regions 43 of the substrate 40. The active regions have their surface portion that is not occupied by the isolation regions 42. Transistor actions occur at the active regions 43 during device operation. Though not shown, the active regions may be formed within well regions.

On the resultant structure having the isolation regions 42, a gate dielectric layer 44, a polysilicon layer 46, a tungsten silicide layer 48 and a mask layer 50 are stacked sequentially. The gate dielectric layer 44 is formed of oxide or nitride. The mask layer 50 is formed of silicon nitride, which is a deposited either by a LPCVD (Low Pressure Chemical Vapor Deposition) method or by a PECVD (Plasma Enhanced Chemical Vapor Deposition) method. The stacked layers are patterned into a plurality of conductive patterns 72 by a photolithography process. Each of the conductive patterns 72 is separated from the others with a selected distance. In this embodiment of the present invention, the conductive patterns 72 are gate electrode patterns of transistors.

Impurity doped regions 68 are shown in the FIG. 14, though not shown in the FIGS. 4 through 13. The impurity doped regions 68 are formed on the active regions by an ion implantation of n-type or p-type impurities using conductive patterns 72 as implantation masks. The impurity doped regions 68 act as source/drain regions of transistors.

A spacer layer is formed on the substrate 40 and the conductive patterns 72. The spacer layer is etched back to form insulating spacers 52 on the sidewalls of the conductive patterns 72. The spacer layer is formed of oxide, which is deposited by the LPCVD method or by the PECVD method. Preferably, the spacer layer is formed of silicon oxide.

The active region in the cell array area can be designed into various kinds of planar shapes. An elliptical region 41, shown in FIG. 15, is one example. But, for better understanding of the scope of the present invention with clarity and simplification, the cross-sectional views in FIGS. 4 through 13 are not limited to any specific shapes. FIG. 14 shows the plan view of the active regions 43, which is described in FIGS. 4 through 13. In the FIG. 14, the impurity doped regions 68 are representing a portion of the active region, and an exposed portion 42′ is representing a portion of the isolation regions 42, which is exposed by the conductive patterns 72 and the spacers 52. The elliptical region 41 of FIG. 15 is not relevant to the cross-sectional views in FIGS. 4 through 13.

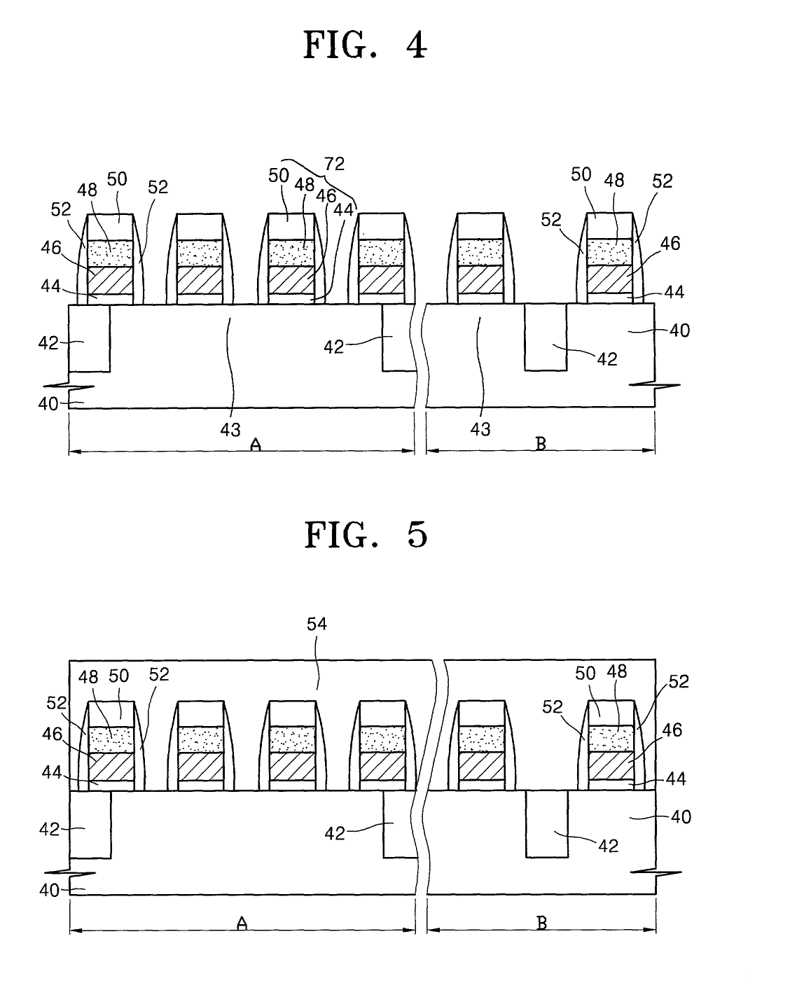

Referring to FIG. 5, a photoresist layer 54 is formed on the whole surface of the resultant structure described above. The photoresist layer 54 is coated thick enough to cover all of spacers 52 and conductive patterns 72.

Referring to FIG. 6, a photoresist layer 54 is patterned into disposable patterns 54′ by an exposure/developing method. The disposable patterns 54′ is formed on a first portion of the spacers and on a first portion of the substrate, where contact windows are to be formed at subsequent process steps. The disposable patterns 54′ can be formed to cover only one of the impurity doped regions 68 as described at the core/peripheral area. Otherwise, The disposable patterns 54′ can be formed to cover a plurality of the impurity doped regions 68 as described at the cell array area. The disposable pattern 54′ in the cell array area can be designed into various kinds of planar shapes. As shown in FIG. 14, the disposable pattern 54′ in the cell array area is T-shaped in this embodiment of the present invention. The T-shaped pattern consists of a horizontal portion and a vertical portion. The vertical portion of the disposable pattern 54′ has a 1st end, which is connected to a central point of the horizontal portion. The T-shaped pattern can be repeated though the entire of the cell array area by an equal-spacing manner or a zigzag manner.

Referring to FIG. 7, an intermediate insulating layer 56 is formed at a temperature under a meting point of the disposable patterns 54′. The intermediate insulating layer 56 covers the whole surface of the resultant structure including the disposable patterns 54′. The intermediate insulating layer 56 is formed of a material selected from the group consisting a SOG (Spin-On Glass) and an oligomer polysilazane. In this embodiment of the present invention, the intermediate insulating layer 56 is formed of the oligomer polysilazane, which is produced by Clariant Corporation using TOSZ as a product name. The intermediate insulating layer 56 is subjected to a soft bake process. The soft bake process is performed at a temperature range 200˜400° C.

In a modified embodiment of the present invention, the intermediate insulating layer 56 may be formed by a two-step deposition method. That is to say, a lower intermediate insulating layer is deposited first by half of a desired thickness. The lower intermediate insulating layer is subjected to the soft bake process to convert the materiality of the lower intermediate insulating layer into quasi-oxide. Continuously, an upper intermediate insulating layer is deposited on the lower intermediate insulating layer so that the composite layer of the lower and upper intermediate insulating layers has the desired thickness. The composite layer is subjected to the soft bake process again.

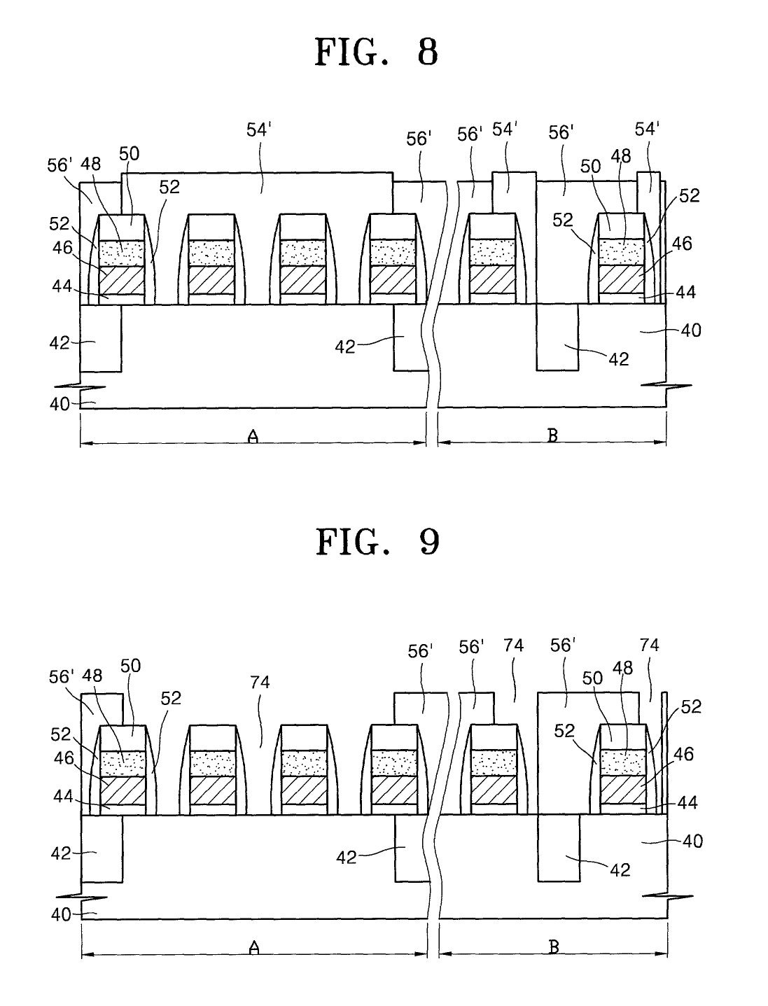

Referring to FIG. 8, an upper portion of the intermediate insulating layer 56 is removed to expose the top surface of the disposable patterns 54′ by either a wet etching process, a dry etching process or a CMP process. The removal of the upper portion of the intermediate insulating layer 56 leaves intermediate insulating patterns 56′. Referring to FIG. 9, the disposable patterns 54′ is selectively removed by an ashing process. The ashing process is performed at low temperature and under an oxygen plasma condition. Subsequently, a cleaning process is performed to perfect the removal of the disposable patterns 54′. The cleaning process is preferably a wet cleaning process. The intermediate insulating patterns 56′ and the spacers 52 define contact windows 74. The intermediate insulating pattern 56′ has a significantly low etch rate against a process condition for the removal of the disposable pattern 54′.

After the cleaning process, the intermediate insulating patterns 56′ are subjected to a hard bake process to fully convert the material of the intermediate insulating patterns into oxide. The hard bake process is performed at a temperature range 600˜800° C. During the hard bake process, the intermediate insulating patterns 56′ shrink, so the contact windows 74 are enlarged. The enlarged contact windows 74 can reduce contact resistance.

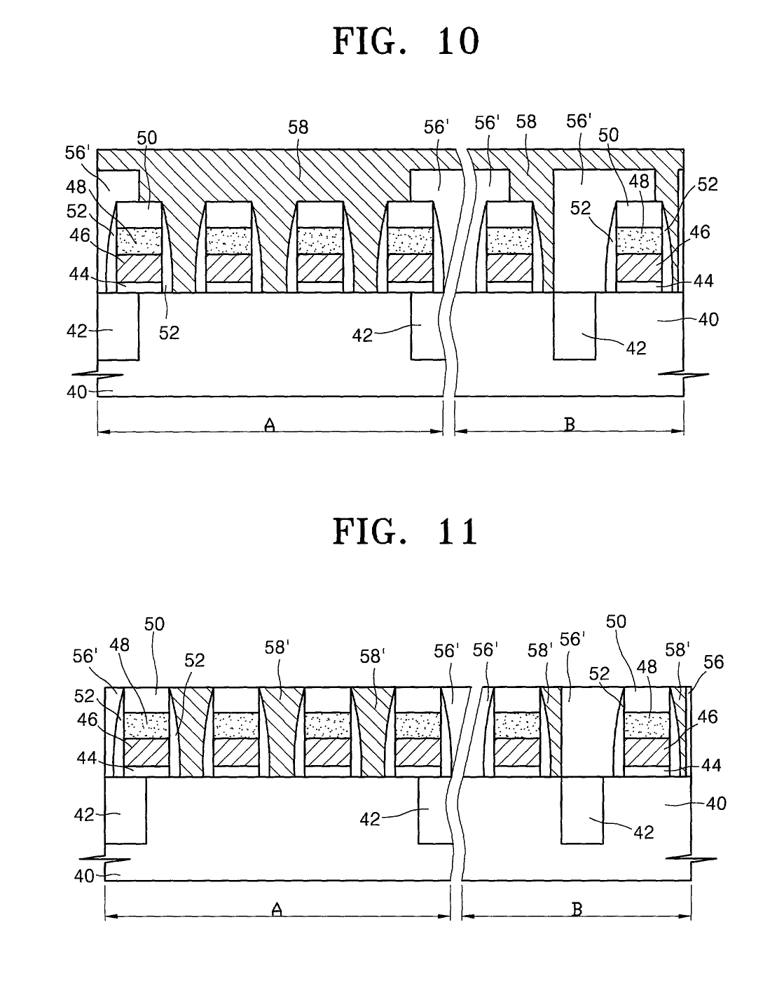

Referring to FIG. 10, a conductive contact layer 58 is formed in the contact window 74 and on the intermediate insulating patterns 56′. The conductive layer 58 is a doped polysilicon layer. The contact layer 58 fills the contact windows 74.

Referring to FIG. 11, an upper portion of the contact layer 58 and an upper portion of the intermediate insulating patterns 56′ are removed by the CMP process to expose the top surface of the conductive patterns 72. As a result, the whole surface of the resultant structure is planarized and conductive contact node patterns 58′ are formed in the contact windows 74. Each of the contact node patterns 58′ make an electrical contact to corresponding one of impurity doped regions 68 and are separated to the other contact node patterns 58′.

Referring to FIG. 12, a 1st ILD (Inter-Layer Dielectric) layer is formed on the resultant structure having the contact node patterns 58′. The 1st ILD layer is patterned to make a DC window 62 in the cell array area to expose a portion of the contact node patterns 58′. The DC window 62 is located at a 2nd end of the vertical portion of the disposable pattern 54′, as shown in the plan view in FIG. 14. FIG. 12 is cross-sectional views which are taken along a line A-A′ of FIG. 14.

Subsequently, a bit line conductive layer is formed on the 1st ILD layer and in the DC window 62. The bit line conductive layer is patterned into a bit line 64, which is extended across the conductive patterns 72. The bit line conductive layer may be formed with two-step deposition process. That is to say, a 1st bit line conductive layer is deposited to fill the DC window 62, and then a 2nd bit line conductive layer is deposited on the resultant structure.

Referring to FIG. 13, a 2nd ILD layer is formed on the resultant structure having the bit line 64. The 2nd ILD layer is patterned to make BC windows 66 in the cell array area to expose the other portion of the contact node patterns 58′. Each of the BC windows 66 is located at two ends of the horizontal portion of the disposable pattern 54′, as shown in the plan view in FIG. 14. FIG. 13 is cross-sectional views which are taken along a line B-B′ of FIG. 14.

Subsequently, a storage electrode layer is formed on the 2nd ILD layer and in the BC windows 66. The storage electrode layer is patterned into storage electrode patterns 68. The storage electrode layer may be formed with two-step deposition process. That is to say, a 1st storage electrode layer is deposited to fill the BC window 66, and then a 2nd storage electrode layer is formed on the resultant structure.

Though not shown, a capacitor dielectric layer and plate electrodes are formed on the storage electrode patterns 68 to form storage capacitors.

According to another embodiment of the present invention, BC windows and DC windows also can be formed in similar ways as described in the previous embodiment, i.e., by using disposable patterns, insulating spacers and intermediate insulating patterns, wherein the intermediate insulating patterns are formed at a temperature under a meting point of the disposable patterns. Each of the BC windows and the DC windows may expose either a portion of an active region or corresponding one of conductive contact node patterns thereunder. The conductive contact node patterns may be located between the spacer adjacent to the sidewall of gate electrode patterns, and may be formed as described in the previous embodiment. Bit lines are electrically connected to upper DC node patterns, which are formed in the DC windows. Storage electrode patterns are electrically connected to upper BC node patterns, which are formed in the BC windows.

According to the present invention, being contrast to the SAC technology, the excessive plasma dry etching process is not needed to expose the portion of the substrate. Therefore, there is no substantial damage on the substrate. In other words, the trap charge density can be minimized to improve threshold voltage characteristic and refresh characteristic comparing the SAC technology.

Moreover, the spacers are made of silicon oxide instead of silicon nitride. The silicon oxide spacers may reduce the tensile stress at the boundary between the spacers and the substrate so as to substantially suppress the GIDL problem. The silicon oxide spacers also reduce the unfavorably high parasitic capacitance between the contact node patterns and the gate electrode patterns, i.e., conductive patterns. This is because the silicon oxide has a lower dielectric constant than the silicon nitride has. In addition, because the spacers are not subject to the excessive plasma dry etching process, the parasitic capacitance may not be more increased.

In the drawings and specification, there have been disclosed typical preferred embodiments of the invention and, although specific terms are employed, they are used in a generic and descriptive sense only and not for purpose of limitation. The embodiments of the present invention can be modified into various other forms, and the scope of the present invention must not be interpreted as being restricted to the embodiments.

What is claimed:

1. A method of fabricating a semiconductor device, comprising:
forming a plurality of conductive patterns on a substrate;
forming a plurality of spacers on sidewalls of the conductive patterns;
forming a disposable pattern on a first portion of the spacers and on a first portion of the substrate, wherein the disposable pattern exposes a second portion of the spacers and a second portion of the substrate;
forming an intermediate insulating pattern on the exposed second portion of the spacers and on the exposed second portion of the substrate;
removing the disposable pattern to expose the first portion of the spacers and the first portion of the substrate, wherein the intermediate insulating pattern defines a contact window; and
forming a contact layer in the contact window.

2. The method of claim 1, wherein the conductive patterns comprise insulating masks, and wherein the contact window exposes a portion of the insulating masks.

3. The method of claim 1, wherein the spacers are formed of silicon oxide.

4. The method of claim 1, wherein the disposable pattern is formed of a photoresist layer.

5. The method of claim 1, wherein the top surface of the disposable pattern is higher than the top surface of the plurality of the conductive patterns.

6. The method of claim 1, wherein the intermediate insulating pattern has a significantly low etch rate relative to a process condition for the removal of the disposable pattern.

7. The method of claim 1, wherein the process of forming the intermediate insulating pattern comprises:
forming an intermediate insulating layer at a temperature under a meting point of the disposable pattern, wherein the intermediate insulating layer covers the disposable pattern; and
removing a portion of the intermediate insulating layer to expose the top surface of the disposable pattern.

8. The method of claim 7, which further comprises subjecting the intermediate insulating layer to a soft bake process.

9. The method of claim 7, wherein the intermediate insulating layer is formed of a material selected from the group consisting of a spin-on glass and an oligomer polysilazane.

10. The method of claim 7, wherein the process of forming the intermediate insulating layer comprises:
forming a lower intermediate insulating layer, wherein the lower intermediate insulating layer covers the disposable pattern;
subjecting the lower intermediate insulating layer to a soft bake process; and
forming an upper intermediate insulating layer on the lower intermediate insulating layer.

11. The method of claim 1, which further comprises subjecting the intermediate insulating pattern to a hard bake process after the removal of the disposable pattern.

12. The method of claim 1, wherein the contact layer is formed further on the intermediate insulating pattern, which further comprises removing a portion of the contact layer and a portion of the intermediate insulating pattern to expose the top surface of the conductive pattern.

13. The method of claim 1, wherein the conductive patterns are gate electrode patterns of transistors, wherein the gate electrode patterns comprise gate dielectric layers, and wherein the substrate is formed of semiconductor material which is electrically contacted to the contact layer.

14. The method of claim 1, wherein the substrate comprises a lower insulating layer and a lower conductive pattern, and wherein the contact window exposes a portion of the lower conductive pattern.

15. The method of claim 14, wherein the lower conductive pattern is a contact node pattern, which is formed between gate electrode patterns of transistors.

16. The method of claim 15, wherein the contact node pattern is electrically connected to a storage electrode of a dynamic random access memory cell.

17. The method of claim 15, wherein the contact node pattern is electrically connected to a bit line electrode of a dynamic random access memory cell.

18. A method of fabricating a semiconductor device, comprising:
forming a plurality of conductive patterns on a substrate;
forming a plurality of spacers on sidewalls of the conductive patterns;
forming an intermediate insulating pattern on a portion of the spacers and on the a portion of the substrate, wherein the intermediate insulating pattern is not formed on a contact window area; and
forming a contact layer in the contact window
wherein the intermediate insulating pattern and the other portion of the spacers define the contact window.

19. The method of claim 18, wherein the conductive patterns comprise insulating masks, and wherein the contact window exposes a portion of the insulating masks.

20. The method of claim 18, wherein the spacers are formed of silicon oxide.
